(19) United States
(12) Patent Application Publication
(10) Pub. No.: US 2020/0343474 A1
(43) Pub. Date: Oct. 29, 2020

(54) THIN FILM ENCAPSULATION STRUCTURE AND THIN FILM ENCAPSULATION METHOD

(71) Applicant: Wuhan China Star Optoelectronics Semiconductor Display Technology Co., Ltd., Wuhan (CN)

(72) Inventor: Rui WANG, Wuhan (CN)

(73) Assignee: Wuhan China Star Optoelectronics Semiconductor Display Technology Co., Ltd., Wuhan (CN)

(21) Appl. No.: 16/462,535

(22) PCT Filed: Mar. 18, 2019
(86) PCT No.: PCT/CN2019/078456

§ 371 Date: May 21, 2019

(30) Foreign Application Priority Data
Dec. 4, 2018 (CN) 201811472511.8

(51) Int. Cl. H01L 51/52; H01L 51/56

(52) U.S. Cl. CPC H01L 51/5237; H01L 2251/56; H01L 2251/301; H01L 51/56

(57) ABSTRACT

A thin film encapsulation structure includes an organic light emitting diode (OLED) device, a first inorganic layer, a grid block wall, an organic layer, and a second inorganic layer. The first inorganic layer covers an upper surface of the OLED device. The grid block wall is formed on an upper surface of the first inorganic layer and includes at least two grids. The organic layer is filled in the grids and deposited on the upper surface of the first inorganic layer. The second inorganic layer covers the grid block wall, an upper surface of the organic layer, the OLED device, and side surfaces of the first inorganic layer.

### BACKGROUND OF INVENTION

### 1. Field of Invention

The present invention relates to a thin film encapsulation structure and a thin film encapsulation method.

### 2. Related Art

Organic light emitting diode (OLED) devices have attracted more and more attention from academia and industry due to advantages of being self-luminous, wide viewing angles, almost infinite high contrast, lower power consumption, and extremely quick response times. After years of active exploration, device structures and processes, and related materials are further optimized, and organic electroluminescence has made long-term progress. OLED displays include organic light emitting units generating excitons in an organic light-emitting layer by a combination of electrons and holes that transition from an excited state to an organic state, thereby to emit light by energy generated when the excitons are generated by the organic light emitting units. However, a cathode and an electroluminescent layer (EML) of an OLED device are easily reacted with permeated water and oxygen, significantly affecting service life and efficiency. As a result, protecting driving units and the organic light emitting units on a flexible substrate by blocking water and oxygen through encapsulation is an essential process.

Currently, mainstream encapsulation methods include thin film encapsulation, glass powder encapsulation, retaining wall encapsulation, and surface adhesive encapsulation. The thin film encapsulation is favored by major panel manufacturers because it is adapted to a bendable display technology. As shown in FIG. 1, an existing OLED encapsulation structure 10, from the inside to the outside, sequentially includes: 1) a base substrate 11, exemplified as a glass or flexible substrate; 2) an electroluminescent unit 12, which includes organic light emitting units configured with three colors, R, G, and B of a pixel array; 3) a first inorganic layer 12, deposited by plasma enhanced chemical vapor deposition (PECVD); 4) an organic layer 14, fabricated by ink jet printing (IJP); 5) a second inorganic layer 15, deposited again by PEVCD.

As shown in FIGS. 2 and 3, in the existing IJP leveling, ink spreads around, and when ink droplets exceed a PECVD boundary, overflow may occur. In such a case, water and oxygen will first enter an organic layer, then permeate from pores of an inorganic layer into an inside of a device, resulting in occurrence of black spots in the device and a decrease in service life of the device. A general solution is to set up two retaining walls around an electroluminescent unit through IJP to enclose the organic layer.

The above-mentioned enclosing method by the retaining walls make an existing process more complicated, and the ink has a risk of overflowing, adversely affecting encapsulation reliability. Besides, during the above-mentioned leveling process, the ink overlaps, and film layers appear undulating, affecting film thickness uniformity. In the encapsulation structure, the inorganic layer functions as a barrier layer to prevent water and oxygen permeation, and the organic layer functions as a buffer layer, releasing a stress of the inorganic layer and increasing the path of permeation of water and oxygen. The two film layers have different functions, different materials, and significant differences in properties, and therefore give rise to problems such as a poor adhesion between the inorganic layer and the organic layer, delamination, peeling of film layers, and a malfunction of the device.

### SUMMARY OF INVENTION

An object of the present invention is to provide a thin film encapsulation structure, capable of effectively overcoming problems that ink dots overflow and overlap, and avoiding delamination between an inorganic layer and an organic layer.

The present invention provides a thin film encapsulation structure, comprising an organic light emitting diode (OLED) device; a first inorganic layer covering an upper surface of the OLED device; a grid block wall formed on an upper surface of the first inorganic layer, and comprising at least two grids; an organic layer filled in the grids and deposited on the upper surface of the first inorganic layer; and a second inorganic layer covering the grid block wall, the upper surface of the organic layer, the OLED device, and side surfaces of the first organic layer.

Further, the grid block wall has a height greater than a thickness of the organic layer.

Still further, the grid block wall has a square shape having a horizontal line inside the square shape, a square shape having two horizontal lines inside the square shape, a square shape having a cross inside the square shape, or a square shape having another square inside the square.

Still further, each of the grids is quadrilateral in shape, and/or a number of the grids is 2 to 16.

Still further, the first inorganic layer, the grid block wall, and the second inorganic layer are all silicon-based compounds.

Still further, the organic layer comprises at least one or a combination of two or more of polyvinyl alcohol, urethane acrylate polymer, and polyimide resin.

Another object of the present invention is to provide a thin film encapsulation method, capable of effectively overcoming problems that ink dots overflow and overlap, and avoiding delamination between an inorganic layer and an organic layer.

The present invention further provides a thin film encapsulation method, comprising steps of a preparation step, performed by providing an organic light emitting diode (OLED) device; a preparation step of a first inorganic layer, performed by forming the first inorganic layer on an upper surface of the OLED device; a preparation step of a grid block wall, performed by forming the grid block wall on an upper surface of the first inorganic layer, wherein the grid block wall comprises at least two grids; a preparation step of an organic layer, performed by filling an organic matter in each of the grids, such that the organic layer is formed by being deposited on the upper surface of the first inorganic layer after the organic matter flows to be leveled onto the corresponding grid; and forming a second inorganic layer on the grid block wall and an upper surface of the organic layer such that the second inorganic layer covers the OLED device, the grid block wall, and side surfaces of the first inorganic layer.

Further, in the preparation step of the organic layer, the organic layer has a thickness less than a height of the grid block wall.

Still further, in the preparation step of the first inorganic layer, the first inorganic layer is deposited by vapor deposition; and/or in the preparation step of the grid block wall, the grid block wall is deposited by vapor deposition; and/or the second inorganic layer is deposited by vapor deposition.

Still further, in the preparation step of the organic layer, the organic matter is filled in each of the grids through inkjet printing.

The present invention has advantageous effects as follows: the present invention provides a thin film encapsulation structure and a thin film encapsulation method utilizing a grid block wall in the thin film encapsulation structure to prevent ink dots from overflowing and overlapping during ink leveling processes, thereby to improve production efficiency, facilitate uniformity of organic film layers, and improve device luminescence performance.

### BRIEF DESCRIPTION OF DRAWINGS

To describe the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

FIG. 1 is a schematic structural view of a conventional thin film encapsulation.

FIG. 2 is a schematic structural view showing ink dots caused by a conventional inkjet printing process.

FIG. 3 is a schematic structural view showing ink flows to be leveled by a conventional inkjet printing process.

FIG. 4 is a schematic structural view of a thin film encapsulation of a first embodiment of the present invention.

FIG. 5 is a schematic longitudinal cross-sectional and structural view of a glass substrate and an organic light emitting display device of the first embodiment of the present invention.

FIG. 6 is a schematic longitudinal cross-sectional and structural view of the glass substrate, the organic light emitting display device, and a first inorganic layer of the first embodiment of the present invention.

FIG. 7 is a schematic structural view of the glass substrate, the organic light emitting display device, the first inorganic layer, and a grid block wall of the first embodiment of the present invention.

FIG. 8 is a schematic structural view of ink dots caused by an inkjet printing process of the first embodiment of the present invention.

FIG. 9 is a schematic structural view of ink flowing to be leveled by the inkjet printing process of the first embodiment of the present invention.

FIG. 10 is a flowchart showing a thin film encapsulation method of the first embodiment of the present invention.

FIG. 11 is a schematic structural view of a glass substrate, an organic light emitting display device, a first inorganic layer, and a grid block wall of a second embodiment of the present invention.

FIG. 12 is a schematic structural view of a glass substrate, an organic light emitting display device, a first inorganic layer, and a grid block wall of a third embodiment of the present invention.

FIG. 13 is a schematic structural view of a glass substrate, an organic light emitting display device, a first inorganic layer, and a grid block wall of a fourth embodiment of the present invention.

FIG. 14 is a schematic structural view of a glass substrate, an organic light emitting display device, a first inorganic layer, and a grid block wall of a fifth embodiment of the present invention.

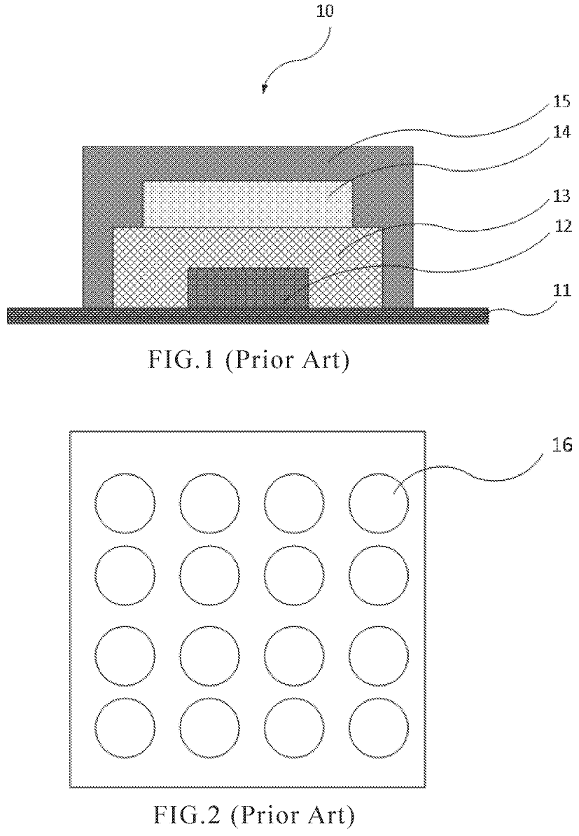

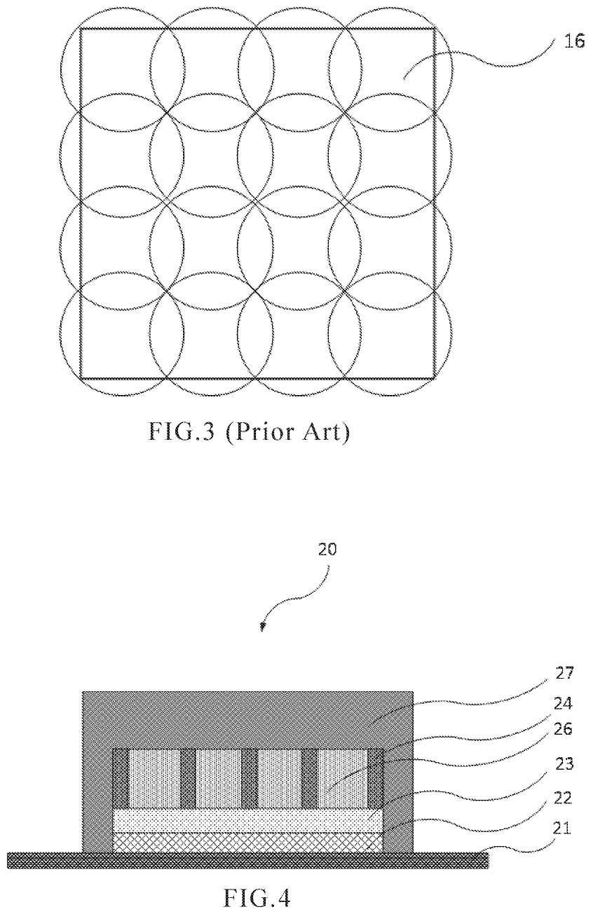

### DESCRIPTION OF PREFERRED EMBODIMENTS

The following embodiments are referring to the accompanying drawings for exemplifying specific implementable embodiments of the present disclosure. Furthermore, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, elements with similar structures are labeled with like reference numerals.

Embodiments of the present invention will be described in detail herein with reference to the drawings. The present invention may be embodied in different forms and the invention is not to be construed as being limited to the specific embodiments set forth herein. The embodiments of the present invention are provided to explain the practical application of the present invention so that those skilled in the art can understand various embodiments of the present invention and various modifications suitable for the intended application.

### Embodiment 1

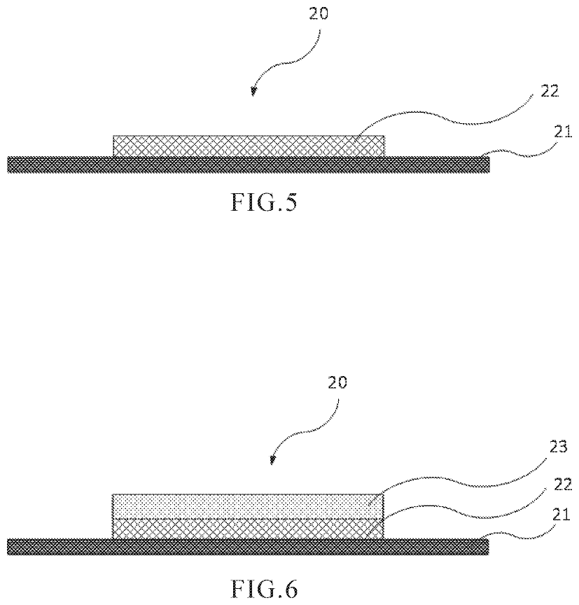

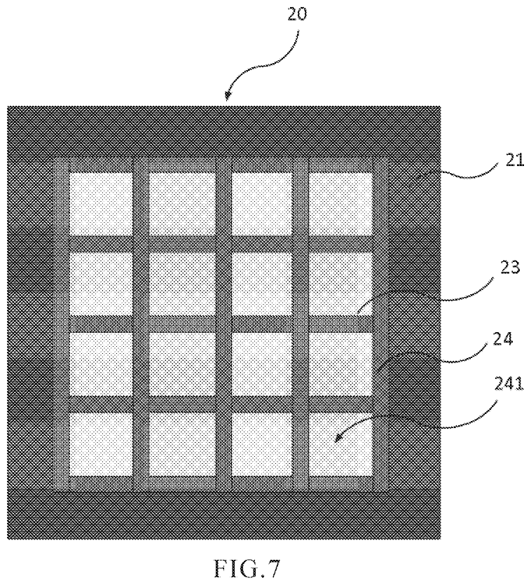

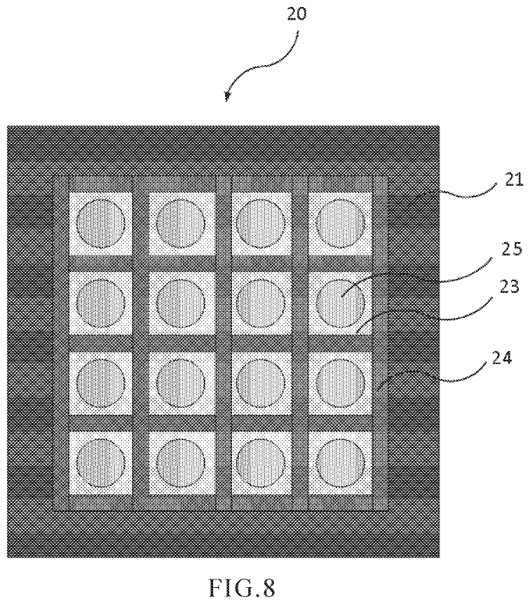

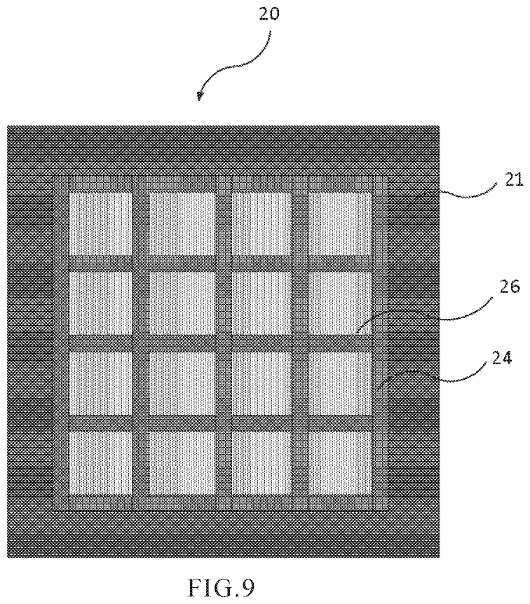

as shown in FIGS. 4-9, the present invention provides a thin film encapsulation structure including an organic light emitting diode (OLED) device 22, a first inorganic layer 23, a grid block wall 24, an organic layer 26, and a second inorganic layer 27. The first inorganic layer 23 covers an upper surface of the OLED device 22. The grid block wall 24 is formed on an upper surface of the first inorganic layer 23 and includes a plurality of grids 241. Each of the grids is circular or polygonal in shape, and preferably is rectangular or square in shape, and/or a number of the grids 241 is between 2-36. In this embodiment, the number is preferably 16, but may be 2, 4, 8, 9, 12, 15, or 25. The organic layer 26 is filled into the grids 241 and is deposited on the upper surface of the first inorganic layer 23.

The second inorganic layer 27 covers the grid block wall 24, an upper surface of the organic layer 26, the OLED device 22, and side surfaces of the first organic layer 23 to effectively avoid permeation of external water and oxygen.

The grid block wall 24 has a height greater than a thickness of the organic layer 26. When ink droplets flow and spread to the quadrilateral grid block wall to be leveled, the grid block wall 24 and each of the grids 241 limit a leveling range of the ink droplets to prevent adjacent droplets from being overlapped, to reach the best film uniformity, and to ensure that the ink droplets do not overflow during preparation processes, thereby to avoid water and oxygen intrusion. In this embodiment, the first inorganic layer 23, the gird block wall 24, and the second inorganic layer 27 are all made of a same material, which is any one or a combination of inorganic materials, such as silicon nitride, silicon oxynitride, silicon oxide, and silicon nitride, and is deposed by plasma enhanced chemical vapor deposition (PEVCD). The organic layer 26 is made of one or a combination of two or more of polyvinyl alcohol, a urethane acrylate polymer, and polyimide resin, and is prepared by an inkjet printing (IJP) process. The grid block wall 24 and the organic layer 26 are disposed in a same IJP chamber during a preparation process.

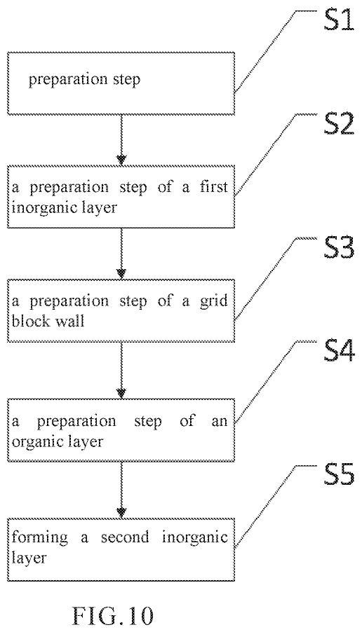

As shown in FIG. 10, in order to prepare the thin film encapsulation, the present invention further provides a thin film encapsulation method including following steps of S1-S5. A preparation step S1, performed by providing an OLED device 22 laminated to a side of a glass substrate, wherein the OLED device includes a hole injection layer, a hole transport layer, an organic light emitting layer, an electron transport layer, and an electron injection layer.

A preparation step of a first inorganic layer S2, performed by preparing a first inorganic layer 23 on an upper surface of the OLED device 22, wherein the first inorganic layer 23 is made of one or a combination of inorganic materials such as silicon nitride, silicon oxynitride, silicon oxide, silicon nitride, and the like, and is deposited on the OLED device 22 by PECVD.

A preparation step of a grid block wall S3, performed by forming the grid block wall on an upper surface of the first inorganic layer, wherein the grid block wall includes a plurality of grids, each of them is quadrilateral in shape. In this embodiment, there are 16 block walls. The grid block wall is deposited on the upper surface of the first inorganic layer by PECVD. The grid block wall 24 is made of any one or a combination of inorganic materials such as silicon nitride, silicon oxynitride, silicon oxide or silicon nitride.

A preparation step of an organic layer S4, performed by filling an organic matter in each of the grids by an inkjet printing technique, such that the organic layer 26 is formed by being deposited on the upper surface of the first inorganic layer 23 after the organic material flows to be leveled onto the corresponding grid. The organic layer 26 has a thickness less than a height of the grid block wall 24. In this manner, when ink droplets 25 flow and spread to the quadrilateral grid block wall to be leveled, the grid block wall 24 and each of the grids 241 limit a leveling range of the ink droplets 25 to prevent adjacent droplets 25 from being overlapped, reach the best film uniformity, and ensure that the ink droplets do not overflow during preparation processes, thereby to avoid water and oxygen intrusion.

A preparation step of a second inorganic layer S5, performed by forming a second inorganic layer 27 on the grid block wall 24 and an upper surface of the organic layer 26 such that the second inorganic layer 27 covers the OLED device 22, the grid block wall 24, and side surfaces of the first inorganic layer 23. The second inorganic layer 27 is made of a combination of any one or more of inorganic materials such as silicon nitride, silicon oxynitride, silicon oxide, silicon nitride, and the like, and is deposited by PECVD.

In the first embodiment, the grid block wall 24 has a height greater than a thickness of the organic layer 26. When the ink droplets 25 flow and spread to the quadrilateral grid block wall to be leveled, the grid block wall 24 limits a leveling range of the ink droplets, so that adjacent droplets do not overlap with each other, thereby to reach the best film uniformity, ensure that the ink droplets do not overflow during preparation processes, and thus avoid water and oxygen intrusion.

### Embodiment 2

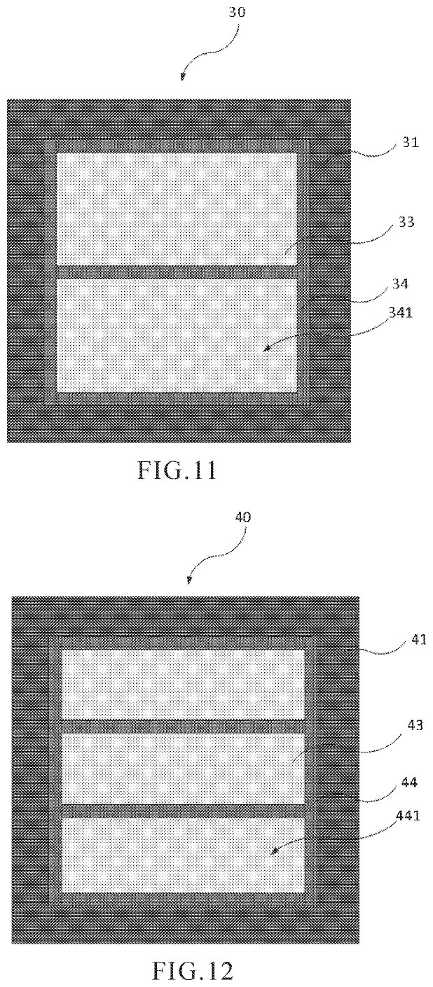

As shown in FIG. 11, the second embodiment is the same as most of technical solutions of the first embodiment, and is distinguished in that, in the second embodiment, a grid block wall 34 is deposited on a first inorganic layer 33 and is composed of two grids 341, wherein the grid block wall has a square shape having a horizontal line inside the square shape.

In the second embodiment, the grid block wall 34 has a height greater than a thickness of an organic layer 36. When the ink droplets flow and spread to the quadrilateral grid block wall to be leveled, the grid block wall 34 limits a leveling range of the ink droplets, so that adjacent droplets do not overlap with each other, thereby to reach the best film uniformity, ensure that the ink droplets do not overflow during preparation processes, and thus avoid water and oxygen intrusion.

### Embodiment 3

As shown in FIG. 12, the third embodiment is the same as most of technical solutions of the first embodiment, and is distinguished in that, in the third embodiment, a grid block wall 44 is deposited on a first inorganic layer 43 and is composed of three grids 431, wherein the grid block wall has a square shape having two horizontal lines inside the square shape.

In the third embodiment, the grid block wall 44 has a height greater than a thickness of an organic layer 46. When the ink droplets flow and spread to the quadrilateral grid block wall to be leveled, the grid block wall 44 limits a leveling range of the ink droplets, so that adjacent droplets do not overlap with each other, thereby to reach the best film uniformity, ensure that the ink droplets do not overflow during preparation processes, and thus avoid water and oxygen intrusion.

### Embodiment 4

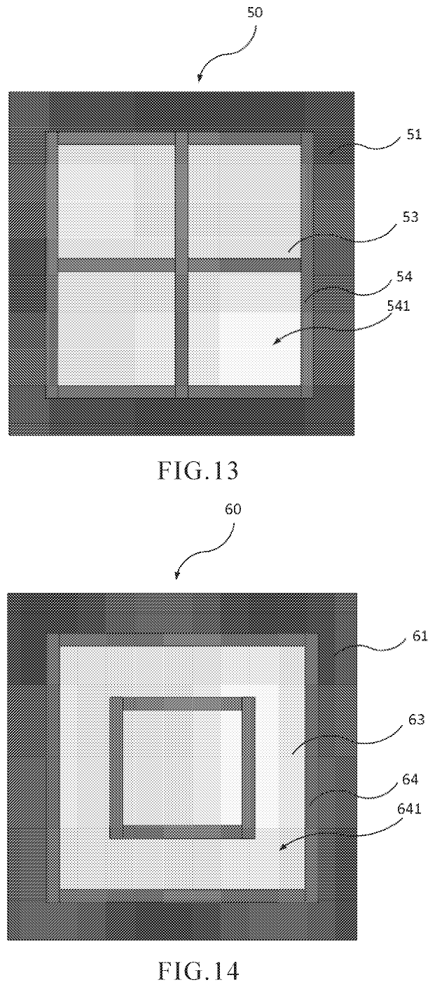

As shown in FIG. 13, the fourth embodiment is the same as most of technical solutions of the first embodiment, and is distinguished in that, in the fourth embodiment, a grid block wall 54 is deposited on a first inorganic layer 53 and is composed of four grids 541, wherein the grid block wall has a square shape having a cross inside the square shape.

In the fourth embodiment, the grid block wall 54 has a height greater than a thickness of an organic layer 56. When the ink droplets flow and spread to the quadrilateral grid block wall to be leveled, the grid block wall 54 limits a leveling range of the ink droplets, so that adjacent droplets do not overlap with each other, thereby to reach the best film uniformity, ensure that the ink droplets do not overflow during preparation processes, and thus avoid water and oxygen intrusion.

### Embodiment 5

As shown in FIG. 14, the fifth embodiment is the same as most of technical solutions of the first embodiment, and is distinguished in that, in the fifth embodiment, a grid block wall 64 is deposited on a first inorganic layer 63 and is composed of two grids 641, wherein the grid block wall has a square shape having another square inside the square shape.

In the fifth embodiment, the grid block wall 64 has a height greater than a thickness of an organic layer 66. When the ink droplets flow and spread to the quadrilateral grid block wall to be leveled, the grid block wall 64 limits a leveling range of the ink droplets, so that adjacent droplets do not overlap with each other, thereby to reach the best film uniformity, ensure that the ink droplets do not overflow during preparation processes, and thus avoid water and oxygen intrusion.

It is understood that the invention may be embodied in other forms within the scope of the claims. Thus the present examples and embodiments are to be considered in all respects as illustrative, and not restrictive, of the invention defined by the claims.

1. A thin film encapsulation structure, comprising:
an organic light emitting diode (OLED) device;
a first inorganic layer covering an upper surface of the OLED device;
a grid block wall formed on an upper surface of the first inorganic layer, and comprising at least two grids;
an organic layer filled in the grids and deposited on the upper surface of the first inorganic layer; and
a second inorganic layer covering the grid block wall, the upper surface of the organic layer, the OLED device, and side surfaces of the first organic layer.

2. The thin film encapsulation structure of claim 1, wherein the grid block wall has a height greater than a thickness of the organic layer.

3. The thin film encapsulation structure of claim 1, wherein the grid block wall has a square shape having a horizontal line inside the square shape, a square shape having two horizontal lines inside the square shape, a square shape having a cross inside the square shape, or a square shape having another square inside the square.

4. The thin film encapsulation structure of claim 1, wherein each of the grids is quadrilateral in shape.

5. The thin film encapsulation structure of claim 1, wherein the first inorganic layer, the grid block wall, and the second inorganic layer are all silicon-based compounds.

6. The thin film encapsulation structure of claim 1, wherein the organic layer comprises at least one or a combination of two or more of polyvinyl alcohol, urethane acrylate polymer, and polyimide resin.

7. A thin film encapsulation method, comprising steps of:
a preparation step, performed by providing an organic light emitting diode (OLED) device;
a preparation step of a first inorganic layer, performed by forming the first inorganic layer on an upper surface of the OLED device;
a preparation step of a grid block wall, performed by forming the grid block wall on an upper surface of the first inorganic layer, wherein the grid block wall comprises at least two grids;
a preparation step of an organic layer, performed by filling an organic matter in each of the grids, such that the organic layer is formed by being deposited on the upper surface of the first inorganic layer after the organic matter flows to be leveled onto the corresponding grid; and
forming a second inorganic layer on the grid block wall and an upper surface of the organic layer such that the second inorganic layer covers the OLED device, the grid block wall, and side surfaces of the first inorganic layer.

8. The thin film encapsulation method of claim 7, wherein in the preparation step of the organic layer, the organic layer has a thickness less than a height of the grid block wall.

9. The thin film encapsulation method of claim 7, wherein in the preparation step of the first inorganic layer, the first inorganic layer is deposited by vapor deposition; and/or in the preparation step of the grid block wall, the grid block wall is deposited by vapor deposition; and/or the second inorganic layer is deposited by vapor deposition.

10. The thin film encapsulation method of claim 7, wherein in the preparation step of the organic layer, the organic matter is filled in each of the grids through inkjet printing.
